(19) United States
(12) Patent Application Publication
(10) Pub. No.: US 2026/0226941 A1
(43) Pub. Date: Aug. 6, 2026

(54) HYBRID BEARING STAGE

(71) Applicant: KLA CORPORATION, Milpitas, CA (US)

(72) Inventor: Aviv BALAN, Mountain View, CA (US)

(21) Appl. No.: 19/046,118

(22) Filed: Feb. 5, 2025

(51) Int. Cl. F16C 29/00; F16C 32/06

(52) U.S. Cl. CPC F16C 29/007; F16C 32/0614

(57) ABSTRACT

A hybrid bearing stage includes at least one guide rail, a carriage translatably coupled to the at least one guide rail, a plurality of air bearings disposed about the carriage, and a mechanical bearing assembly coupled to the at least one guide rail. The mechanical bearing assembly includes a mechanical bearing guide extending along a length of the at least one guide rail, a plurality of bearing blocks coupled to the mechanical bearing guide, a mounting block coupled to the carriage and positioned adjacent the plurality of bearing blocks, and a flexure mechanism extending between the mounting block and the plurality of bearing blocks. The plurality of bearing blocks apply a damping force to the carriage via contact between the plurality of bearing blocks and the mounting block.

### FIELD OF THE INVENTION

The embodiments described herein relate to semiconductor inspection devices, and more specifically, to hybrid bearing stages for semiconductor wafer inspection.

### BACKGROUND

Semiconductor wafer stages are traditionally used for positioning wafers with high precision during an inspection process. These stages typically utilize a “step and repeat” inspection process, in which the stage quickly moves the wafer into an inspection position and abruptly stops to acquire a high-resolution image of the wafer in the inspection position. However, due to the rapid movement of the wafer about the stage, the wafer may be allowed to settle in the inspection position prior to obtaining an image of the wafer, which may impact the speed and overall efficiency of the stage.

Conventional stages are often guided by either mechanical bearings or air bearings. Mechanical bearing stages may provide stiffness and friction to the stage, which may aid in minimizing the amount of time it takes the wafer to settle in the inspection position. However, mechanical bearings often include imperfections which prevent the wafer from traveling in a straight path across the stage. These imperfections compromise the repeatability of traditional “step and repeat” processes, such that it may be difficult to implement mechanical bearings in stages that require high levels of precision.

In contrast, air bearing stages may enable the wafer to hover over a flat surface, thereby eliminating mechanical contact and allowing for enhanced accuracy and motion in positioning the wafer. However, the lack of friction present in air bearing stages results in increased settling time for the wafer at the inspection position, as the wafer may continue to vibrate once moved to the inspection position. The increased settling time common in air bearing stages may result in difficulties performing “step and repeat” processes that require rapid stabilization of the wafer.

Accordingly, a need exists for a wafer stage that allows for reliable and repeatable implementation of traditional “step and repeat” processes while minimizing the settling time of the wafer at various inspection positions across the stage.

### SUMMARY OF THE INVENTION

In the embodiments provided herein, a hybrid bearing stage is disclosed. The hybrid bearing stage includes at least one guide rail, a carriage translatably coupled to the at least one guide rail, a plurality of air bearings disposed about the carriage, and a mechanical bearing assembly coupled to the at least one guide rail. The mechanical bearing assembly includes a mechanical bearing guide extending along a length of the at least one guide rail, a plurality of bearing blocks coupled to the mechanical bearing guide, a mounting block coupled to the carriage and positioned adjacent the plurality of bearing blocks, and a flexure mechanism extending between the mounting block and the plurality of bearing blocks. The plurality of bearing blocks apply a damping force to the carriage via contact between the plurality of bearing blocks and the mounting block.

In other embodiments, a hybrid bearing stage for inspecting a wafer is disclosed. The hybrid bearing stage includes at least one guide rail, a carriage that supports the wafer and is translatably coupled to the at least one guide rail, a plurality of lateral air bearings positioned between the carriage and a surface of the hybrid bearing stage, a plurality of longitudinal air bearings positioned between the carriage and the at least one guide rail, and a mechanical bearing assembly coupled to the at least one guide rail. The mechanical bearing assembly includes a mechanical bearing guide extending along a length of the at least one guide rail, a plurality of bearing blocks coupled to the mechanical bearing guide, a mounting block coupled to the carriage and positioned adjacent the plurality of bearing blocks, and a flexure mechanism extending between the mounting block and the plurality of bearing blocks. The plurality of longitudinal air bearings generate a first pressurized air gap between the carriage and the at least one guide rail, the plurality of lateral air bearings generate a second pressurized air gap between the carriage and the surface of the hybrid bearing stage, and the plurality of bearing blocks apply a damping force to the carriage, such that the damping force does not compromise the first pressurized air gap and the second pressurized air gap.

In yet another embodiment still, a method of inspecting a wafer using a hybrid bearing stage is disclosed. The method includes activating a plurality of lateral air bearings to generate a first pressurized air gap between a carriage and a surface of the hybrid bearing stage, translating the carriage to a desired lateral position on the surface of the hybrid bearing stage, activating a plurality of longitudinal air bearings to generate a second pressurized air gap between the carriage and at least one guide rail of the hybrid bearing stage, translating the carriage relative the at least one guide rail to a desired longitudinal position on the surface of the hybrid bearing stage, engaging a mechanical bearing assembly of the hybrid bearing stage, such that a plurality of bearing blocks apply a damping force to the carriage, and capturing a high-resolution image of the wafer at an inspection point corresponding to the desired longitudinal position and the desired lateral position.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 is a perspective view of a hybrid bearing stage, according to one or more embodiments shown and described herein;

FIG. 2 is a partial cross-sectional view of the hybrid bearing stage of FIG. 1, according to one or more embodiments shown and described herein;

FIG. 3 is a partial perspective view of a mechanical bearing assembly of the hybrid bearing stage of FIG. 1, according to one or more embodiment shown and described herein;

FIG. 4 is a partial perspective view of the mechanical bearing assembly of FIG. 3, according to one or more embodiments shown and described herein; and

FIG. 5 is an illustrative flow diagram of a method of inspecting a wafer using the hybrid bearing stage of FIG. 1, according to one or more embodiments shown and described herein.

### DETAILED DESCRIPTION

Embodiments disclosed herein relate to hybrid bearing stages. The hybrid bearing stage may include at least one guide rail, a carriage translatably coupled to the at least one guide rail, a plurality of air bearings disposed between the carriage and the at least one rail, and a mechanical bearing assembly coupled to the at least one guide rail. The mechanical bearing assembly includes a mechanical bearing guide extending along a length of the at least one guide rail, a plurality of bearing blocks coupled to the mechanical bearing guide, a mounting block coupled to the carriage and positioned adjacent the plurality of bearing blocks, and a flexure mechanism extending between the mounting block and the plurality of bearing blocks. The plurality of bearing blocks apply a damping force to the carriage via contact between the plurality of bearing blocks and the mounting block. In these embodiments, the plurality of air bearings may allow for the frictionless translation of the carriage in the lateral and longitudinal directions, while the damping force afforded by the mechanical bearing guide may act to minimize settling time of a wafer disposed on the carriage as the carriage rapidly translates about the hybrid bearing stage between inspection positions.

As noted hereinabove, traditional wafer stages may utilize either air bearings or mechanical bearings to move a wafer about the stage for inspection. However, mechanical bearing stages may include imperfections that compromise the repeatability of traditional wafer inspection processes, while the lack of friction present in air bearing stages may increase the settling time of the wafer at various inspection points across the stage. Accordingly, wafer inspection processes, such as “step and repeat” processes, may be difficult to quickly and efficiently perform on traditional wafer stages.

The hybrid bearing stage described herein aims to address these shortcomings by integrating a mechanical bearing assembly in an air bearing stage. By utilizing mechanical bearings in the air bearing stage, the disclosed hybrid bearing stage may provide the precision and motion of an air bearing stage while reducing the settling time of a wafer via the mechanical bearings, as will be described in detail herein. Furthermore, in the embodiments described herein, a flexure connection may be used to connect the mechanical bearing assembly to the air bearing stage, thereby ensuring that the mechanical bearing assembly does not interfere with the accuracy of the air bearings.

Embodiments of hybrid bearing stages will now be described in detail herein. The following will now describe these hybrid stages in more detail with reference to the drawings and where like numbers refer to like structures.

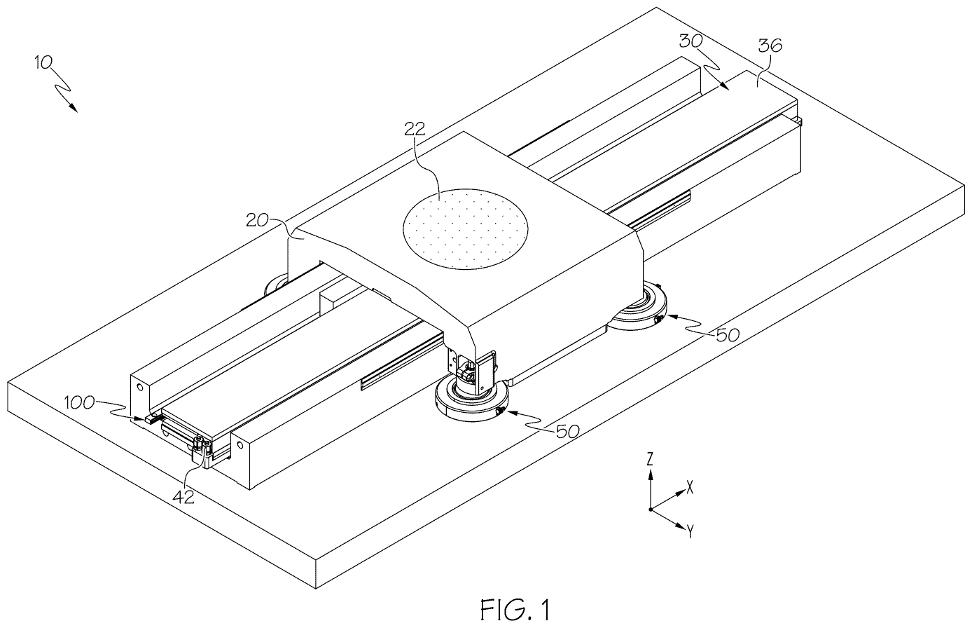

Referring now to FIG. 1, a hybrid bearing stage 10 is depicted. In the embodiments described herein, the term “hybrid bearing stage” may refer to a stage, such as a semiconductor wafer stage, that includes a variety of different bearings (air, mechanical, etc.) for translating a wafer across a surface of the stage, as will be described in additional detail herein.

As depicted in FIG. 1, the hybrid bearing stage 10 may include a carriage 20, which may be used to translate a wafer 22 across a surface of the hybrid bearing stage 10. In these embodiments, the carriage 20 may be translated in a variety of coordinate directions (e.g., along the x-axis and/or y-axis as depicted in the coordinate axis of FIG. 1) in order to align the wafer 22 with an inspection tool (not depicted) at various inspection positions across the hybrid bearing stage 10. It should be appreciated that, in these embodiments, the carriage 20 provides a structural support for the wafer 22 as the wafer 22 is moved across the hybrid bearing stage 10.

In the embodiments described herein, the hybrid bearing stage 10 may include at least one guide rail 30 to guide the carriage 20 as the carriage 20 (and wafer 22) traverses the surface of the hybrid bearing stage 10. For example, as shown in FIG. 1, the at least one guide rail 30 may include at least one longitudinal guide rail 36, which may be configured to translate the carriage 20 in a longitudinal direction (e.g., in the +/−x-direction as depicted in the coordinate axis of FIG. 1) across the hybrid bearing stage. In these embodiments, the carriage 20 may be disposed about the at least one longitudinal guide rail 36, such that the carriage 20 may translate along the at least one longitudinal guide rail 36 in the longitudinal direction.

As further illustrated in FIG. 1, the hybrid bearing stage 10 may further include a longitudinal actuator 42, such as a servomotor or other similar driving mechanism, that is configured to translate the carriage 20 about the at least one longitudinal guide rail 36 in order to move the wafer 22 into the inspection position. In these embodiments, the carriage 20 may translate about the longitudinal guide rail 36 (e.g., via longitudinal actuator 42) until the carriage 20 achieves a desired longitudinal position on the hybrid bearing stage 10. It should be appreciated that, in these embodiments, the inspection position may correspond to the position in which the carriage 20 achieves the desired longitudinal position on the surface of the hybrid bearing stage 10.

Although not depicted, in some embodiments, it should be appreciated that the at least one guide rail 30 may include a plurality of guide rails. For example, the hybrid bearing stage 10 may further include at least a first lateral guide rail and a second lateral guide rail, which may be configured to translate the carriage 20 in a lateral direction (e.g., +/−y-direction as depicted in the coordinate axis of FIG. 1) along the hybrid bearing stage 10. In other embodiments still, the hybrid bearing stage 10 may include a plurality of transverse guide rails, such as a first transverse guide rail and a second transverse guide rail, which may be configured to translate the carriage 20 in a transverse direction (e.g., in the +/−z-direction as depicted in the coordinate axis of FIG. 1). Accordingly, it should be appreciated that the carriage 20 may be communicatively coupled to any number of guide rails in order to move the carriage 20 in a desired coordinate direction relative a surface of the hybrid bearing stage 10.

In some embodiments, it should be further appreciated that the carriage 20 may be configured to rotate in order to align various portions of the wafer 22 with the inspection tool (not depicted) at a particular inspection position. In these embodiments, a portion of the carriage 20 which supports the wafer 22 may be rotatable relative a base of the carriage 20 in order to provide the rotational positioning of the wafer 22 described herein.

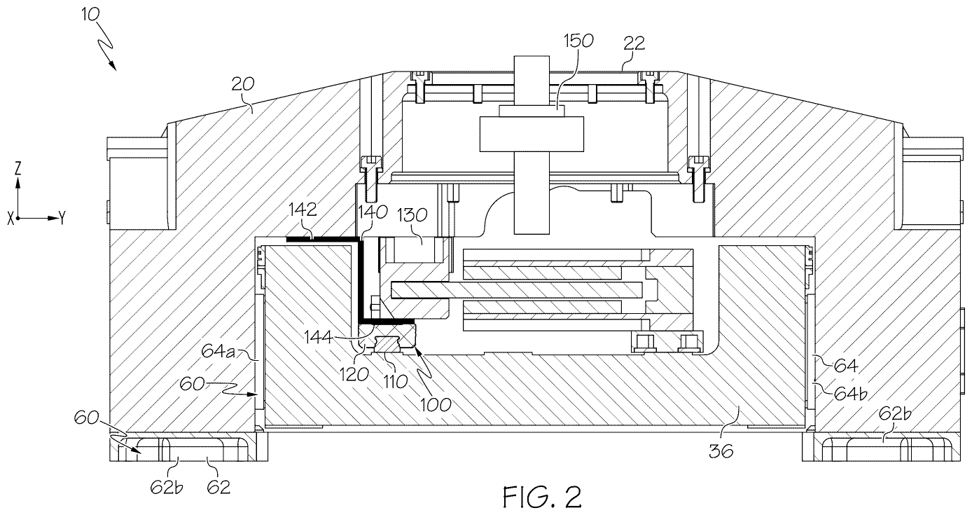

Referring now to FIGS. 1 and 2, the hybrid bearing stage 10 may further include an air bearing assembly 50, which may be configured to allow rapid and precise movement of the carriage 20 about the hybrid bearing stage 10. In these embodiments, the air bearing assembly 50 may include a plurality of air bearings 60 disposed about the carriage 20, which may be configured to enable frictionless movement of the carriage 20 in the longitudinal and lateral directions, as will be described in detail herein.

For example, as most clearly depicted in FIG. 2, the plurality of air bearings 60 may include a plurality of lateral air bearings 62 and a plurality of longitudinal air bearings 64, which may be configured to allow for frictionless translation of the carriage 20 in the lateral and longitudinal directions, respectively. In these embodiments, the plurality of lateral air bearings 62 may include at least a first lateral air bearing 62a and a second lateral air bearing 62b, with each of the first lateral air bearing 62a and the second lateral air bearing 62b being positioned on a bottom side of the carriage 20 and/or at least one longitudinal guide rail 36, such that the first lateral air bearing 62a and the second lateral air bearing 62b are positioned between the carriage 20 and/or the at least one longitudinal guide rail 36 and the surface of the hybrid bearing stage 10. Accordingly, when the first lateral air bearing 62a and the second lateral air bearing 62 b are activated, pressurized air may form a gap (e.g., 3-10 microns in the +/−z-direction as depicted in the coordinate axis of FIG. 2) between the carriage 20 and/or the longitudinal guide rail 36 and the surface of the hybrid bearing stage 10. In these embodiments, the gap formed by the pressurized air generated by the plurality of lateral air bearings 62 may enable frictionless movement of the carriage about the hybrid bearing stage 10.

Referring still to FIG. 2, it should be further appreciated that the plurality of longitudinal air bearings 64 may similarly enable frictionless movement of the carriage 20. In these embodiments, the plurality of longitudinal air bearings 64 may include at least a first longitudinal air bearing 64a and a second longitudinal air bearing 64b, with the first longitudinal air bearing 64a and the second longitudinal air bearing 64b being positioned between the carriage 20 and the longitudinal guide rail 36. Accordingly, when the first longitudinal air bearing 64a and the second longitudinal air bearing 64b are activated, pressurized air may form a gap (e.g., 3-10 microns in the +/−y-direction as depicted in the coordinate axis of FIG. 2) between the carriage 20 and the longitudinal guide rail 36. In these embodiments, the gap formed by the pressurized air generated by the plurality of longitudinal air bearings 64 may enable frictionless movement of the carriage 20 along the longitudinal guide rail 36 in the longitudinal direction (e.g., in the +/−x-direction as depicted in the coordinate axis of FIG. 2).

Referring now to FIGS. 2-4, the hybrid bearing stage 10 may further include a mechanical bearing assembly 100, which may be configured to introduce controlled friction into the carriage 20 to minimize settling time of the carriage 20 (and in turn, wafer 22) as the carriage 20 translates between various inspection points on the hybrid bearing stage 10. In these embodiments, the mechanical bearing assembly 100 may include a mechanical bearing guide 110, a plurality of bearing blocks 120, and a mounting block 130 extending between the plurality of bearing blocks 120 and the carriage 20, as will be described in additional detail herein.

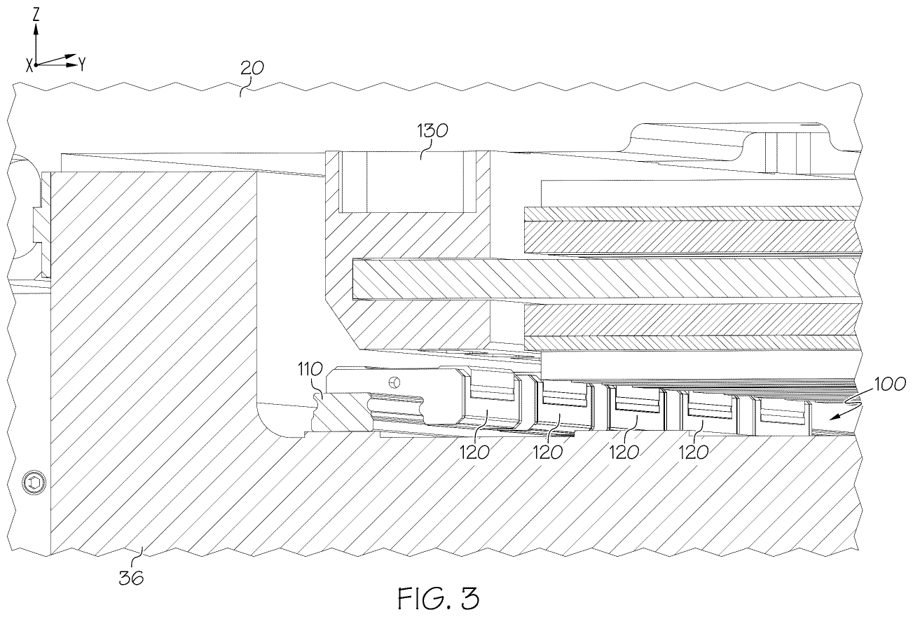

As most clearly depicted in FIGS. 2 and 3, the mechanical bearing guide 110 may extend in the longitudinal direction along a length of the longitudinal guide rail 36. In these embodiments, it should be appreciated that the mechanical bearing guide 110 may extend along an entire length of the longitudinal guide rail 36, such that the mechanical bearing assembly 100 may be configured to provide a frictional force to the carriage 20 at any longitudinal position along the length of the longitudinal guide rail 36.

Referring still to FIGS. 2 and 3, the mounting block 130 may be coupled to the carriage 20, such that the mounting block 130 is positioned adjacent to the mechanical bearing guide 110 when the carriage 20 is positioned about the longitudinal guide rail 36. In these embodiments, the plurality of bearing blocks 120 may be coupled to the mechanical bearing guide 110 such that the plurality of bearing blocks 120 extend at least partially between the mechanical bearing guide 110 and the mounting block 130.

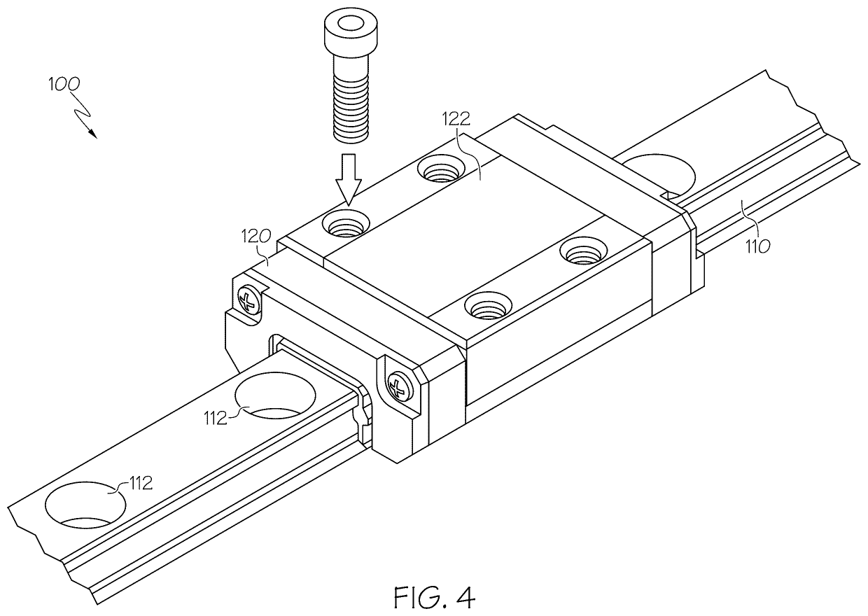

As depicted most clearly in FIG. 4, the mechanical bearing guide 110 may include a plurality of openings 112 which may be used to secure the mechanical bearing guide 110 to the longitudinal guide rail 36. For example, in these embodiments, fasteners, such as screws, pins, or any other similar fastener, may extend through the plurality of openings 112 formed in the mechanical bearing guide 110 and corresponding openings (not depicted) formed in the longitudinal guide rail 36 to fix the mechanical bearing guide 110 to the longitudinal guide rail 36.

In these embodiments, the plurality of bearing blocks 120 may be coupled about the mechanical bearing guide 110, such that the plurality of bearing blocks 120 may translate along the mechanical bearing guide 110. In these embodiments, the plurality of bearing blocks 120 may translate along the length of the mechanical bearing guide 110 as the carriage 20 translates along the length of the longitudinal guide rail 36. It should be appreciated that, by translatably coupling the plurality of bearing blocks 120 to the mechanical bearing guide 110, it may be possible to provide controlled friction to the carriage 20 at any position along the length of the mechanical bearing guide 110 while minimizing the number of the plurality of bearing blocks 120 that are secured to the mechanical bearing guide 110. However, in other embodiments, it should be understood that the plurality of bearing blocks 120 may be fixedly coupled to the mechanical bearing guide 110, such that the plurality of bearing blocks 120 are stationary. In these embodiments, the plurality of bearing blocks 120 may include a number of bearing blocks 120 sufficient to extend along an entire length of the mechanical bearing guide 110, such that the mechanical bearing assembly 100 is able to provide controlled friction to the carriage 20 at any position along a length of the mechanical bearing guide 110 while the plurality of bearing blocks 120 remain stationary.

Referring again to FIGS. 2-4, the mechanical bearing assembly 100 may further include a flexure mechanism 140 that extends between the plurality of bearing blocks 120 and the mounting block 130 and further couples the mechanical bearing assembly 100 to the carriage 20. As provided herein, the flexure mechanism 140 may be a compliant mechanical component that allows controlled flexibility while maintaining stiffness in a desired direction, as will be described in detail herein.

For example, as depicted most clearly in FIG. 2, the flexure mechanism 140 may be a z-shaped flexure, with an upper portion 142 coupled to an upper surface of the longitudinal guide rail 36 and a lower portion 144 extending between the plurality of bearing blocks 120 and the mounting block 130. In these embodiments, the flexure mechanism may allow controlled movement in a first direction, such as a damping force direction (e.g., in the +/−z-direction as depicted in the coordinate axis of FIG. 2), while remaining rigid in other coordinate directions (e.g., in the +/−y-direction and/or the +/−x-direction as depicted in the coordinate axis of FIG. 2). Accordingly, the flexure mechanism 140 may allow for the plurality of bearing blocks 120 to apply a friction force (e.g., damping force) to the carriage 20 via the mounting block 130 without disturbing the operation of the plurality of lateral air bearings 62 or the plurality of longitudinal air bearings 64.

In the embodiments described herein, the flexure mechanism 140 may be formed of metal (e.g., stainless steel, titanium, etc.), composite material (e.g., carbon fiber, polymer, etc.), alloys (e.g., aluminum alloys, invar, etc.), or any other similar material configured to provide the compliant characteristics described herein without departing from the scope of the present disclosure. Furthermore, although the flexure mechanism 140 is depicted as being a z-shaped flexure, it should be understood that, in some embodiments, the flexure mechanism may be a blade flexure, a torsional flexure, a hinge flexure, a leaf spring flexure, or any other similar type of flexure mechanism without departing from the scope of the present disclosure.

Referring again to FIGS. 2-4, in these embodiments, the hybrid bearing stage 10 may further include a feedback system, such as a controller 150, that is configured to monitor and control the positioning of the carriage 20 on the hybrid bearing stage 10 in real time. For example, the controller 150 may include a linear encoder used to measure the position of the carriage 20 along the at least one guide rail 30 (e.g., the longitudinal guide rail 36). In the embodiments described herein, the controller 150 may be used to align the carriage 20, and in turn, the wafer 22, with inspection positions of a wafer inspection tool, as has been described in detail herein.

Referring now to FIGS. 1-4 collectively, operation of the hybrid bearing stage 10 will now be described in additional detail. In these embodiments, the controller 150 may determine an inspection position having a coordinate position on the surface of the hybrid bearing stage 10. Initially, the controller 150 may be configured to activate the plurality of lateral air bearings 62, such that pressurized air from the plurality of lateral air bearings 62 forms a gap between the carriage 20 and/or longitudinal guide rail 36 and the surface of the hybrid bearing stage 10. Accordingly, the carriage 20 may be quickly and easily moved to the coordinate position corresponding to the inspection position, as the gap formed by the plurality of lateral air bearings 62 may enable frictionless translation of the carriage 20 about the surface of the hybrid bearing stage 10.

In these embodiments, the controller 150 may further translate the carriage 20 along the longitudinal guide rail 36 and to the coordinate position corresponding to the inspection position. In these embodiments, the controller 150 may further activate the plurality of longitudinal air bearings 64, such that pressurized air from the plurality of longitudinal air bearings 64 forms a gap between the carriage 20 and the longitudinal guide rail 36. Accordingly, the carriage 20 may be quickly and easily moved to the coordinate position corresponding to the inspection position, as the gap formed by the plurality of longitudinal air bearings 64 may enable frictionless translation of the carriage 20 relative the longitudinal guide rail 36.

It should be further appreciated that the inspection processes described herein may be performed at significant speeds. Accordingly, the lateral and longitudinal translation (e.g., activation of the plurality of lateral air bearings 62 and the plurality of longitudinal air bearings 64) of the carriage 20 may occur simultaneously in order to more quickly and efficiently move the carriage 20 into the inspection position.

Referring still to FIGS. 1-4, as the carriage 20 is translated to the inspection position, the mechanical bearing assembly 100 may provide a damping force to the carriage 20 in order to minimize the time needed for the carriage 20 to settle at the inspection position. For example, in these embodiments, the plurality of bearing blocks 120 may each include a damping mechanism 122, such as a friction pad, spring, or any other similar damping mechanism, which engages the portion of the flexure mechanism 140 that extends between the plurality of bearing blocks 120 and the mounting block 130. As the mechanical bearing assembly 100 is engaged, the damping mechanism 122 of each of the plurality of bearing blocks 120 may apply a damping force (e.g., frictional or otherwise) to the mounting block 130 coupled to the carriage 20 (e.g., via the flexure mechanism 140), which may aid in stabilizing the carriage 20, and in turn, the wafer 22 as the carriage 20 reaches the inspection position.

Although FIGS. 1-4 depict the air bearing assembly 50 and the mechanical bearing assembly 100 as being used to aid in translating the at least one longitudinal guide rail 36, it should be appreciated that the air bearing assembly 50 and the mechanical bearing assembly 100 may be similarly implemented on the at least one guide rail 30 to enhance the settling time of the carriage 20 as it translates in any coordinate direction across the surface of the hybrid bearing stage 10. For example, as provided hereinabove with reference to FIG. 1, in embodiments in which the at least one guide rail 30 includes a plurality of guide rails, such as a first lateral guide rail and a second lateral guide rail, the air bearing assembly 50 and the mechanical bearing assembly 100 may be disposed on the first and second lateral guide rail to minimize settling time of the carriage 20 as it moves in a lateral direction. Accordingly, it should be understood that the hybrid bearing stage of FIG. 1 is intended to be illustrative in nature, and the at least one guide rail 30, the air bearing assembly 50, and the mechanical bearing assembly 100 may be implemented to move the carriage 20 in any coordinate direction without departing from the scope of the present disclosure.

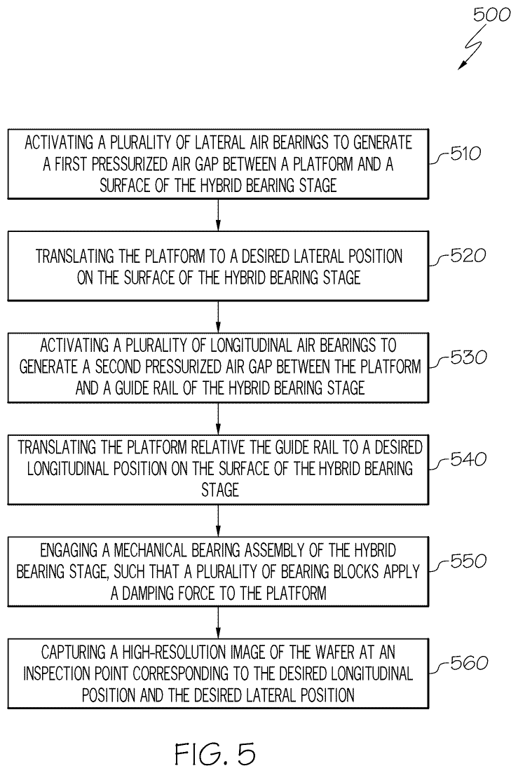

Referring now to FIG. 5, a method 500 of performing wafer inspection using the hybrid bearing stage of FIGS. 1-4 will now be described in detail. In these embodiments, the method may initially involve activating a plurality of lateral air bearings to generate a first pressurized air gap between a carriage and a surface of the hybrid bearing stage, as is depicted at block 510. Once the first pressurized air gap is generated, the method may advance to block 520, which may include translating the carriage to a desired lateral position on the surface of the hybrid bearing stage.

Referring still to FIG. 5, the method may similarly involve activating a plurality of longitudinal air bearings to generate a second pressurized air gap between the carriage and a longitudinal guide rail of the hybrid bearing stage, as depicted at block 530. In these embodiments, once the second pressurized air gap is formed, the method may advance to block 540, which may involve translating the carriage to a desired longitudinal position on the surface of the hybrid bearing stage.

It should be appreciated that the wafer inspection processes described herein occur at rapid speeds. Accordingly, the method steps of blocks 510-540 may, in some embodiments, be performed simultaneously, such that the carriage may be more quickly positioned at a desired location on the surface of the hybrid bearing stage for inspection.

As further depicted in FIG. 5, the method may further involve engaging a mechanical bearing assembly of the hybrid bearing stage, such that a plurality of bearing blocks apply a damping force to the carriage, as shown at block 550. In these embodiments, due to the rapid speed at which the inspection processes occur, the wafer positioned on the carriage may continue to move (e.g., vibrate, etc.) once the carriage reaches a desired inspection position. However, the damping force applied to the carriage may act to stabilize the wafer, thereby enhancing the speed and efficiency at which the wafer may be inspected.

In these embodiments, once the wafer is stabilized, the method may advance to block 560, which may involve capturing a high-resolution image of the wafer at an inspection point corresponding to the desired longitudinal position and the desired lateral position. The high resolution image of the wafer may be used to confirm that various dimensions of the wafer are accurate before the wafer is implemented in additional semiconductor manufacturing processes.

In view of the foregoing, it should be appreciated that the embodiments described herein are related to hybrid bearing stages for performing inspection processes on wafers. The hybrid bearing stage may include at least one guide rail, a carriage translatably coupled to the at least one guide rail, a plurality of air bearings disposed between the carriage and the at least one guide rail, and a mechanical bearing assembly coupled to the at least one guide rail. The mechanical bearing assembly includes a mechanical bearing guide extending along a length of the at least one guide rail, a plurality of bearing blocks coupled to the mechanical bearing guide, a mounting block coupled to the carriage and positioned adjacent the plurality of bearing blocks, and a flexure mechanism extending between the mounting block and the plurality of bearing blocks. The plurality of bearing blocks apply a damping force to the carriage via contact between the plurality of bearing blocks and the mounting block. In these embodiments, the plurality of air bearings may allow for the frictionless translation of the carriage in any coordinate direction, while the damping force afforded by the mechanical bearing guide may act to minimize settling time of a wafer disposed on the carriage as the carriage rapidly translates about the hybrid bearing stage between inspection positions.

The embodiments disclosed herein may be further described with reference to the following aspects:

According to one aspect of the disclosure, and potentially in combination with other disclosed aspects of the disclosure, a hybrid bearing stage is disclosed. The hybrid bearing stage includes at least one guide rail, a carriage translatably coupled to the at least one guide rail, a plurality of air bearings disposed about the carriage, and a mechanical bearing assembly coupled to the at least one guide rail. The mechanical bearing assembly includes a mechanical bearing guide extending along a length of the at least one guide rail, a plurality of bearing blocks coupled to the mechanical bearing guide, a mounting block coupled to the carriage and positioned adjacent the plurality of bearing blocks, and a flexure mechanism extending between the mounting block and the plurality of bearing blocks. The plurality of bearing blocks apply a damping force to the carriage via contact between the plurality of bearing blocks and the mounting block.

According to one aspect of the disclosure, and potentially in combination with other disclosed aspects of the disclosure the flexure mechanism is a z-shaped flexure mechanism.

According to one aspect of the disclosure, and potentially in combination with other disclosed aspects of the disclosure, the z-shaped flexure mechanism includes an upper portion coupled to the at least one guide rail and a lower portion extending between the plurality of bearing blocks and the mounting block, such that the z-shaped flexure mechanism allows the damping force to be applied from the plurality of bearing blocks to the carriage.

According to one aspect of the disclosure, and potentially in combination with other disclosed aspects of the disclosure, the mechanical bearing guide extends along an entire length of the at least one guide rail.

According to one aspect of the disclosure, and potentially in combination with other disclosed aspects of the disclosure, the plurality of bearing blocks are translatably coupled to the mechanical bearing guide, such that the plurality of bearing blocks are configured to translate along a length of the mechanical bearing guide.

According to one aspect of the disclosure, and potentially in combination with other disclosed aspects of the disclosure, the mechanical bearing guide includes a plurality of openings for fixedly coupling the mechanical bearing guide to the at least one guide rail.

According to one aspect of the disclosure, and potentially in combination with other disclosed aspects of the disclosure, each of the plurality of bearing blocks further include a damping mechanism configured to apply the damping force to the mounting block.

According to one aspect of the disclosure, and potentially in combination with other disclosed aspects of the disclosure, the hybrid bearing stage further includes a feedback system including a controller configured to monitor a coordinate position of the carriage relative a surface of the hybrid bearing stage.

According to one aspect of the disclosure, and potentially in combination with other disclosed aspects of the disclosure, the plurality of air bearings includes a plurality of lateral air bearings positioned between the carriage and a surface of the hybrid bearing stage.

According to one aspect of the disclosure, and potentially in combination with other disclosed aspects of the disclosure, the plurality of lateral air bearings are configured to generate a pressurized air gap between the carriage and the surface of the hybrid bearing stage, such that the plurality of lateral air bearings enable frictionless movement of the carriage.

According to one aspect of the disclosure, and potentially in combination with other disclosed aspects of the disclosure, the plurality of air bearings further include a plurality of longitudinal air bearings positioned between the carriage and the at least one guide rail.

According to one aspect of the disclosure, and potentially in combination with other disclosed aspects of the disclosure, the plurality of longitudinal air bearings are configured to generate a pressurized air gap between the carriage and the at least one guide rail, such that the plurality of longitudinal air bearings enable frictionless movement of the carriage.

According to one aspect of the disclosure, and potentially in combination with other disclosed aspects of the disclosure, the pressure air gap between the carriage and the at least one guide rail is less than or equal to 10 microns.

According to one aspect of the disclosure, and potentially in combination with other disclosed aspects of the disclosure, the hybrid bearing stage further includes an actuator for translating the carriage relative the at least one guide rail.

According to one aspect of the disclosure, and potentially in combination with other disclosed aspects of the disclosure, a hybrid bearing stage for inspecting a wafer is disclosed. The hybrid bearing stage includes at least one guide rail, a carriage that supports the wafer and is translatably coupled to the at least one guide rail, a plurality of lateral air bearings positioned between the carriage and a surface of the hybrid bearing stage, a plurality of longitudinal air bearings positioned between the carriage and the at least one guide rail, and a mechanical bearing assembly coupled to the at least one guide rail. The mechanical bearing assembly includes a mechanical bearing guide extending along a length of the at least one guide rail, a plurality of bearing blocks coupled to the mechanical bearing guide, a mounting block coupled to the carriage and positioned adjacent the plurality of bearing blocks, and a flexure mechanism extending between the mounting block and the plurality of bearing blocks. The plurality of longitudinal air bearings generate a first pressurized air gap between the carriage and the at least one guide rail, the plurality of lateral air bearings generate a second pressurized air gap between the carriage and the surface of the hybrid bearing stage, and the plurality of bearing blocks apply a damping force to the carriage, such that the damping force does not compromise the first pressurized air gap and the second pressurized air gap.

According to one aspect of the disclosure, and potentially in combination with other disclosed aspects of the disclosure, the flexure mechanism is a z-shaped flexure mechanism.

According to one aspect of the disclosure, and potentially in combination with other disclosed aspects of the disclosure, the z-shaped flexure mechanism includes an upper portion coupled to the at least one guide rail and a lower portion extending between the plurality of bearing blocks and the mounting block, such that the z-shaped flexure mechanism allows the damping force to be applied from the plurality of bearing blocks to the carriage.

According to one aspect of the disclosure, and potentially in combination with other disclosed aspects of the disclosure, each of the plurality of bearing blocks further include a damping mechanism configured to apply the damping force to the carriage.

According to one aspect of the disclosure, and potentially in combination with other disclosed aspects of the disclosure, the hybrid bearing stage further includes a feedback system including a controller configured to monitor a coordinate position of the carriage relative the surface of the hybrid bearing stage.

According to one aspect of the disclosure, and potentially in combination with other disclosed aspects of the disclosure, a method of inspecting a wafer using a hybrid bearing stage is disclosed. The method includes activating a plurality of lateral air bearings to generate a first pressurized air gap between a carriage and a surface of the hybrid bearing stage, translating the carriage to a desired lateral position on the surface of the hybrid bearing stage, activating a plurality of longitudinal air bearings to generate a second pressurized air gap between the carriage and at least one guide rail of the hybrid bearing stage, translating the carriage relative the at least one guide rail to a desired longitudinal position on the surface of the hybrid bearing stage, engaging a mechanical bearing assembly of the hybrid bearing stage, such that a plurality of bearing blocks apply a damping force to the carriage, and capturing a high-resolution image of the wafer at an inspection point corresponding to the desired longitudinal position and the desired lateral position.

The terminology used herein is for the purpose of describing particular aspects only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. The term “or a combination thereof” means a combination including at least one of the foregoing elements.

It is noted that the terms “substantially ” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A hybrid bearing stage comprising:
at least one guide rail;
a carriage translatably coupled to the at least one guide rail;
a plurality of air bearings disposed about the carriage; and
a mechanical bearing assembly coupled to the at least one guide rail, the mechanical bearing assembly comprising:
a mechanical bearing guide extending along a length of the at least one guide rail;
a plurality of bearing blocks coupled to the mechanical bearing guide;
a mounting block coupled to the carriage and positioned adjacent the plurality of bearing blocks; and
a flexure mechanism extending between the mounting block and the plurality of bearing blocks;
wherein the plurality of bearing blocks apply a damping force to the carriage via contact between the plurality of bearing blocks and the mounting block.

2. The hybrid bearing stage of claim 1, wherein the flexure mechanism is a z-shaped flexure mechanism.

3. The hybrid bearing stage of claim 2, wherein the z-shaped flexure mechanism includes an upper portion coupled to the at least one guide rail and a lower portion extending between the plurality of bearing blocks and the mounting block, such that the z-shaped flexure mechanism allows the damping force to be applied from the plurality of bearing blocks to the carriage.

4. The hybrid bearing stage of claim 1, wherein the mechanical bearing guide extends along an entire length of the at least one guide rail.

5. The hybrid bearing stage of claim 1, wherein the plurality of bearing blocks are translatably coupled to the mechanical bearing guide, such that the plurality of bearing blocks are configured to translate along a length of the mechanical bearing guide.

6. The hybrid bearing stage of claim 1, wherein the mechanical bearing guide includes a plurality of openings for fixedly coupling the mechanical bearing guide to the at least one guide rail.

7. The hybrid bearing stage of claim 1, wherein each of the plurality of bearing blocks further include a damping mechanism configured to apply the damping force to the mounting block.

8. The hybrid bearing stage of claim 1, further comprising a feedback system including a controller configured to monitor a coordinate position of the carriage relative a surface of the hybrid bearing stage.

9. The hybrid bearing stage of claim 1, wherein the plurality of air bearings includes a plurality of lateral air bearings positioned between the carriage and a surface of the hybrid bearing stage.

10. The hybrid bearing stage of claim 9, wherein the plurality of lateral air bearings are configured to generate a pressurized air gap between the carriage and the surface of the hybrid bearing stage, such that the plurality of lateral air bearings enable frictionless movement of the carriage.

11. The hybrid bearing stage of claim 9, wherein the plurality of air bearings further include a plurality of longitudinal air bearings positioned between the carriage and the at least one guide rail.

12. The hybrid bearing stage of claim 11, wherein the plurality of longitudinal air bearings are configured to generate a pressurized air gap between the carriage and the at least one guide rail, such that the plurality of longitudinal air bearings enable frictionless movement of the carriage.

13. The hybrid bearing stage of claim 12, wherein the pressure air gap between the carriage and the at least one guide rail is less than or equal to 10 microns.

14. The hybrid bearing stage of claim 1, further comprising an actuator for translating the carriage relative the at least one guide rail.

15. A hybrid bearing stage for inspecting a wafer, the hybrid bearing stage comprising:
at least one guide rail;
a carriage that supports the wafer and is translatably coupled to the at least one guide rail;
a plurality of lateral air bearings positioned between the carriage and a surface of the hybrid bearing stage;
a plurality of longitudinal air bearings positioned between the carriage and the at least one guide rail;
a mechanical bearing assembly coupled to the at least one guide rail, the mechanical bearing assembly comprising:
a mechanical bearing guide extending along a length of the at least one guide rail;
a plurality of bearing blocks coupled to the mechanical bearing guide;
a mounting block coupled to the carriage and positioned adjacent the plurality of bearing blocks; and
a flexure mechanism extending between the mounting block and the plurality of bearing blocks;
wherein the plurality of longitudinal air bearings generate a first pressurized air gap between the carriage and the at least one guide rail, the plurality of lateral air bearings generate a second pressurized air gap between the carriage and the surface of the hybrid bearing stage, and the plurality of bearing blocks apply a damping force to the carriage, such that the damping force does not compromise the first pressurized air gap and the second pressurized air gap.

16. The hybrid bearing stage of claim 15, wherein the flexure mechanism is a z-shaped flexure mechanism.

17. The hybrid bearing stage of claim 16, wherein the z-shaped flexure mechanism includes an upper portion coupled to the at least one guide rail and a lower portion extending between the plurality of bearing blocks and the mounting block, such that the z-shaped flexure mechanism allows the damping force to be applied from the plurality of bearing blocks to the carriage.

18. The hybrid bearing stage of claim 15, wherein each of the plurality of bearing blocks further include a damping mechanism configured to apply the damping force to the carriage.

19. The hybrid bearing stage of claim 15, further comprising a feedback system including a controller configured to monitor a coordinate position of the carriage relative the surface of the hybrid bearing stage.

20. A method for inspecting a wafer using a hybrid bearing stage, the method comprising:
activating a plurality of lateral air bearings to generate a first pressurized air gap between a carriage and a surface of the hybrid bearing stage;
translating the carriage to a desired lateral position on the surface of the hybrid bearing stage;
activating a plurality of longitudinal air bearings to generate a second pressurized air gap between the carriage and at least one guide rail of the hybrid bearing stage;
translating the carriage relative the at least one guide rail to a desired longitudinal position on the surface of the hybrid bearing stage;
engaging a mechanical bearing assembly of the hybrid bearing stage, such that a plurality of bearing blocks apply a damping force to the carriage; and
capturing a high-resolution image of the wafer at an inspection point corresponding to the desired longitudinal position and the desired lateral position.
